(19) United States
(12) Patent Application Publication
(10) Pub. No.: US 2016/0093743 A1
(43) Pub. Date: Mar. 31, 2016

(54) THIN FILM TRANSISTOR SUBSTRATE AND METHOD OF FABRICATING THE SAME

(71) Applicant: Samsung Display Co., Ltd., Yongin-city (KR)

(72) Inventors: Bong-Kyun KIM, Yongin-city (KR); Sang-Won Shin, Yongin-city (KR); Jong-Hyun Choung, Yongin-city (KR)

(21) Appl. No.: 14/816,767

(22) Filed: Aug. 3, 2015

(30) Foreign Application Priority Data
Sep. 26, 2014 (KR) 10-2014-0129202

(51) Int. Cl. H01L 29/786; H01L 29/24; H01L 29/45; H01L 27/12; H01L 29/423; H01L 21/445; H01L 21/4763; H01L 29/66; H01L 29/417

(52) U.S. Cl. CPC H01L 29/7869; H01L 29/66969; H01L 29/24; H01L 29/45; H01L 29/41733; H01L 29/42384; H01L 21/445; H01L 21/47635; H01L 27/124; H01L 27/1259

(57) ABSTRACT

A thin film transistor substrate includes a gate electrode disposed on a substrate; a semiconductor layer partially overlapping the gate electrode, the semiconductor layer including an oxide semiconductor material; a source electrode and a drain electrode disposed on the semiconductor layer, the source electrode and the drain electrode including a barrier layer, a main wiring layer disposed on the barrier layer, and a first capping layer disposed on the main wiring layer and being spaced apart from each other; and second capping layers covering lateral surfaces of the main wiring layers of the source and drain electrodes.

### CROSS-REFERENCE TO RELATED APPLICATION

This application claims priority from and the benefit of Korean Patent Application No. 10-2014-0129202, filed on Sep. 26, 2014, which is hereby incorporated by reference for all purposes as if fully set forth herein.

### BACKGROUND

1. Field

Exemplary embodiments relate to a thin film transistor substrate and a method of fabricating the same, and, more particularly, to a thin film transistor substrate with improved reliability and a method of fabricating the same.

2. Discussion of the Background

An active-matrix display device uses a thin film transistor as a switching device or a driving device, and includes a gate line for transmitting a scan signal for controlling the thin film transistor, and a data line for transmitting a signal applied to a pixel electrode. As a size of the display device increases, to implement high-speed driving, research has been conducted on an oxide semiconductor technique and a technique for decreasing resistance of the signal line. Particularly, a copper material has been used to decrease resistance of the signal line. However, the copper may be vulnerable to oxidation by reacting with oxygen. Oxidation of the signal line may cause deterioration of reliability of the TFT.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a thin film transistor substrate with improved reliability.

Additional aspects will be set forth in the detailed description which follows, and, in part, will be apparent from the disclosure, or may be learned by practice of the inventive concept.

According to exemplary embodiments, a thin film transistor substrate, including: a gate electrode disposed on a substrate; a semiconductor layer partially overlapping the gate electrode, the semiconductor layer including an oxide semiconductor material; a source electrode and a drain electrode disposed on the semiconductor layer, the source electrode and the drain electrode including a barrier layer, a main wiring layer disposed on the barrier layer, and a first capping layer disposed on the main wiring layer and being spaced apart from each other; and second capping layers covering lateral surfaces of the main wiring layers of the source and drain electrodes.

According to exemplary embodiments, a method of fabricating a thin film transistor substrate, the method including: forming a gate electrode on a base substrate; forming a semiconductor layer partially overlapping the gate electrode, the semiconductor layer including an oxide semiconductor material; forming a conductive layer including a barrier layer, a main wiring layer, and a first capping layer sequentially disposed on the semiconductor layer; patterning the conductive layer to form a conductive pattern that partially overlaps the gate electrode; forming a thin film transistor, formation of thin film transistor including patterning the conductive pattern to remove a portion of the conductive pattern that partially overlaps the gate electrode; and forming a second capping layer covering a lateral surface of the main wiring layer.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a plan view illustrating a display device including a thin film transistor substrate, according to one or more exemplary embodiments.

FIG. 2 is a cross-sectional view of the display device of FIG. 1 taken along sectional line I-I′, according to one or more exemplary embodiments.

FIG. 3 is an enlarged view of region A of FIG. 2, according to one or more exemplary embodiments.

FIGS. 4, 5, 6, 7, 8, and 9 are respective cross-sectional views of a display device at various stages of manufacture, according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

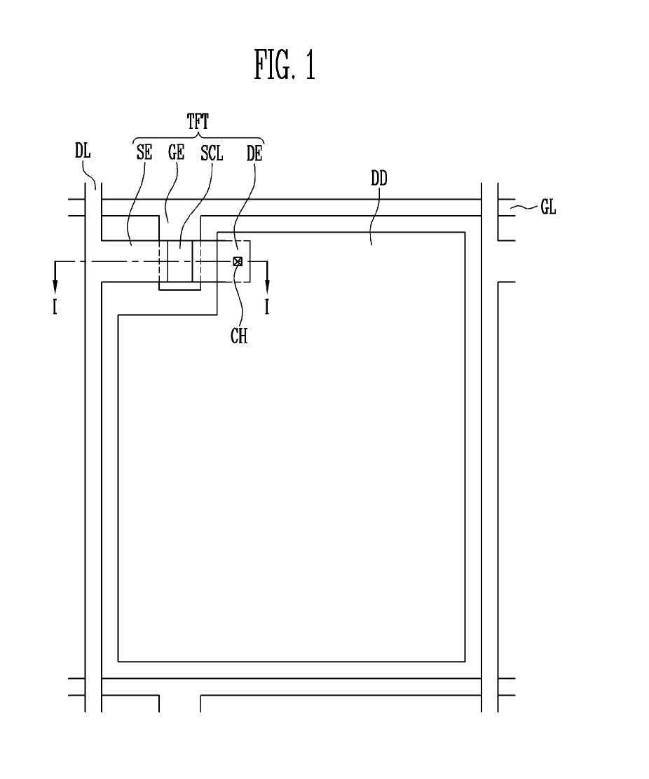

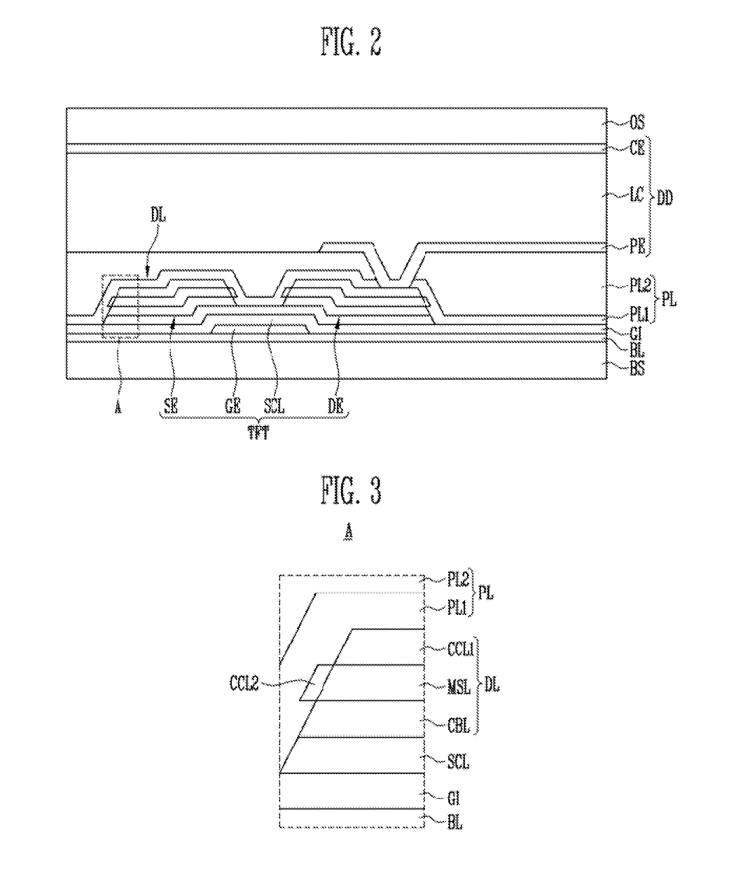

FIG. 1 is a top plan view illustrating a display device including a thin film transistor substrate, according to one or more exemplary embodiments, FIG. 2 is a cross-sectional view of the display device of FIG. 1 taken along sectional line I-I′, according to one or more exemplary embodiments, and FIG. 3 is an enlarged view of region A of FIG. 2, according to one or more exemplary embodiments.

Referring to FIGS. 1, 2, and 3, the display device includes a thin film transistor substrate, an opposing substrate OS opposite to the thin film transistor substrate, and a display device DD disposed between the thin film transistor substrate and the opposing substrate OS.

The thin film transistor substrate includes a base substrate BS, and a thin film transistor TFT disposed on the base substrate BS. The thin film transistor TFT may be connected to a gate line GL and a data line DL that are disposed on the base substrate BS and the gate line GL and the data line DL extends cross each other.

The base substrate BS includes a transparent insulating material to allow light to pass through. Further, the base substrate BS may be a rigid type substrate and a flexible type substrate. The rigid type substrate includes at least one of a glass substrate, a quartz substrate, a glass ceramic substrate, and a crystalline glass substrate. The flexible type substrate includes a film substrate including at least one of a polymer organic material and a plastic substrate. The material included in the base substrate BS may have resistance (or heat resistance) to a high processing temperature involved during a fabricating process.

An insulating layer BL may be disposed between the base substrate BS and the thin film transistor TFT. The insulating layer BL may include at least one of a silicon oxide layer and a silicon nitride layer. The insulating layer BL prevents or reduces impurities from being diffused to the thin film transistor TFT, and prevents or reduces moisture and oxygen from permeating. Further, the insulating layer BL may flatten a surface of the base substrate BS. Depending on a case, the insulating layer BL may also be omitted.

The thin film transistor TFT may include a gate electrode GE, a semiconductor layer SCL partially overlapping the gate electrode GE, a source electrode SE connected to one end of the semiconductor layer SCL, and a drain electrode DE connected to the other end of the semiconductor layer SCL.

The gate electrode GE may be disposed on the insulating layer BL, and overlap the semiconductor layer SCL. The gate electrode GE may be formed as a protruded part of the gate line GL. The gate electrode GE may include at least one of aluminum (Al), an aluminum alloy (Al-alloy), silver (Ag), tungsten (W), cooper (Cu), nickel (Ni), chrome (Cr), molybdenum (Mo), titanium (Ti), platinum (Pt), tantalum (Ta), neodymium (Nd), scandium (Sc), and an alloy thereof

A gate insulating layer GI may be disposed on the gate electrode GE to insulate the semiconductor layer SCL and the gate electrode GE. The gate insulating layer GI may include at least one of a silicon oxide layer and a silicon nitride layer. For example, the gate insulating layer GI may have a structure in which the silicon oxide layer and the silicon nitride layer are stacked.

The semiconductor layer SCL may be disposed on the gate insulating layer GI, and may include an oxide semiconductor material. The oxide semiconductor material may include at least one of zinc (Zn), indium (In), gallium (Ga), and tin (Sn). For example, the semiconductor layer SCL may include an indium-gallium-zinc oxide (IGZO). the semiconductor layer SCL may include channel regions of the thin film transistor TFT between regions of the semiconductor layer SCL that are connected with the source electrode SE and the drain electrode DE.

The source electrode SE may be disposed on the semiconductor layer SCL. The source electrode SE may be formed as a protruded part of the data line DL. The drain electrode DE may be disposed on the semiconductor layer SCL spaced apart from the source electrode SE.

The source electrode SE, the drain electrode DE, and the data line DL may include a barrier layer CBL, a main wiring layer MSL disposed on the barrier layer CBL, and a first capping layer CCL1 disposed on the main wiring layer MSL. Lateral surfaces of the main wiring layer MSL may be covered by a second capping layer CCL2.

First, the main wiring layer MSL may include a low resistance material, such as copper and/or a copper alloy.

The barrier layer CBL may prevent or block a copper material included in the main wiring layer MSL from being diffused to the semiconductor layer SCL. The barrier layer CBL may include a transparent conductive oxide. For example, the barrier layer CBL may include at least one of an indium-zinc oxide (IZO), a gallium-zinc oxide (GZO), and an aluminum-zinc oxide (AZO). Here, a content of the zinc oxide (ZnO) in the transparent conductive oxide may be equal to or more than 70 wt % of the total weight.

The first capping layer CCL1 may include the same material as that of the barrier material CBL. That is, the first capping layer CCL may include at least one of an indium-zinc oxide (IZO), a gallium-zinc oxide (GZO), and an aluminum-zinc oxide (AZO). Here, a content of the zinc oxide (ZnO) in the transparent conductive oxide may be equal to or more than 70 wt % of the total weight.

The second capping layer CCL2 may cover the lateral surfaces of the main wiring layer MSL to prevent or reduce oxidation of the lateral surface of the main wiring layer MSL. The second capping layer CCL2 may include at least one of nickel-phosphorus, nickel-boron, gold-nickel, tin-lead, tin, and silver. For example, the second capping layer CCL2 may be an electroless nickel plated layer including nickel-phosphorus. Here, the second capping layer CCL2 may contain phosphorus of 8 wt % to 15 wt % of the total weight. Further, a thickness of the second capping layer CCL2 may be 0.1 μm to 1.5 μm.

A passivation layer PL may be disposed on the thin film transistor TFT. The passivation layer PL may include one or more layers. For example, the passivation layer PL may include an inorganic passivation layer PL1, and an organic passivation layer PL2 disposed on the inorganic passivation layer PL1. The inorganic passivation layer PL1 may include at least one of a silicon oxide layer and a silicon nitride layer. The organic passivation layer PL2 may include at least one of acryl, polyimide (PI), polyamide (PA), and benzocycloubutene (BCB). The organic passivation layer PL2 may be a flattening layer, which is transparent and flexible to smooth and flatten a curve of a lower structure.

The passivation layer PL may include a contact hole CH for exposing a part of the drain electrode DE. The display device DD connected to the drain electrode DE through the contact hole CH may be disposed on the passivation layer PL.

The display device DD may include a first electrode PE, a second electrode CE disposed facing the first electrode PE, and an optical layer disposed between the first electrode PE and the second electrode CE, wherein the optical layer may adjust light to pass through and/or generate light.

The display device DD may be any one of a liquid crystal display (LCD) device, an electrophoretic display (EPD) device, an electrowetting display (EWD) device, and an organic light emitting display (OLED) device. For convenience of the description, the present exemplary embodiment is explained to include the liquid crystal display device. Accordingly, the optical layer may be a liquid crystal layer LC. Further, although not illustrated in the drawing, the display device DD of the present exemplary embodiment may display an image by using light provided from a backlight unit.

The first electrode PE may be disposed on the passivation layer PL, and may be connected to the drain electrode DE through the contact hole CH. Further, the first electrode PE may include a transparent conductive oxide, such as an Indium Tin Oxide (ITO) and/or an Indium Zinc Oxide (IZO).

The optical layer LC includes a plurality of liquid crystal molecules. The liquid crystal molecules may be arranged in a specific direction by an electric field formed by the first electrode PE and the second electrode CE to adjust a transmittance of light provided from a backlight unit. Accordingly, the optical layer LC adjusts the light provided from the backlight unit to pass through by the electric field to make the display device DD display an image.

The second electrode CE may include a transparent conductive oxide, such as an Indium Tin Oxide (ITO) and/or an Indium Zinc Oxide (IZO), similar to the first electrode PE. The second electrode CE receives a common voltage Vcom provided from an external device. The second electrode CE may be disposed on one surface of the opposing substrate OS facing the base substrate BS.

The opposing substrate OS may also include a color filter (not shown) for implementing a predetermined color by using the light provided from the backlight unit. The color filter may have any one color among a red color, a green color, a blue color, and/or a white color, and may be formed by a process, such as deposition or coating. However, the exemplary embodiments are not limited thereto.

In the thin film transistor substrate, the main wiring layer MSL is covered by the first capping layer CCL1 and the second capping layer CCL2. Accordingly, the main wiring layer MSL is not exposed to the outside, thereby being prevented or protected from oxidation. Accordingly, it is possible to improve the reliability of the thin film transistor TFT.

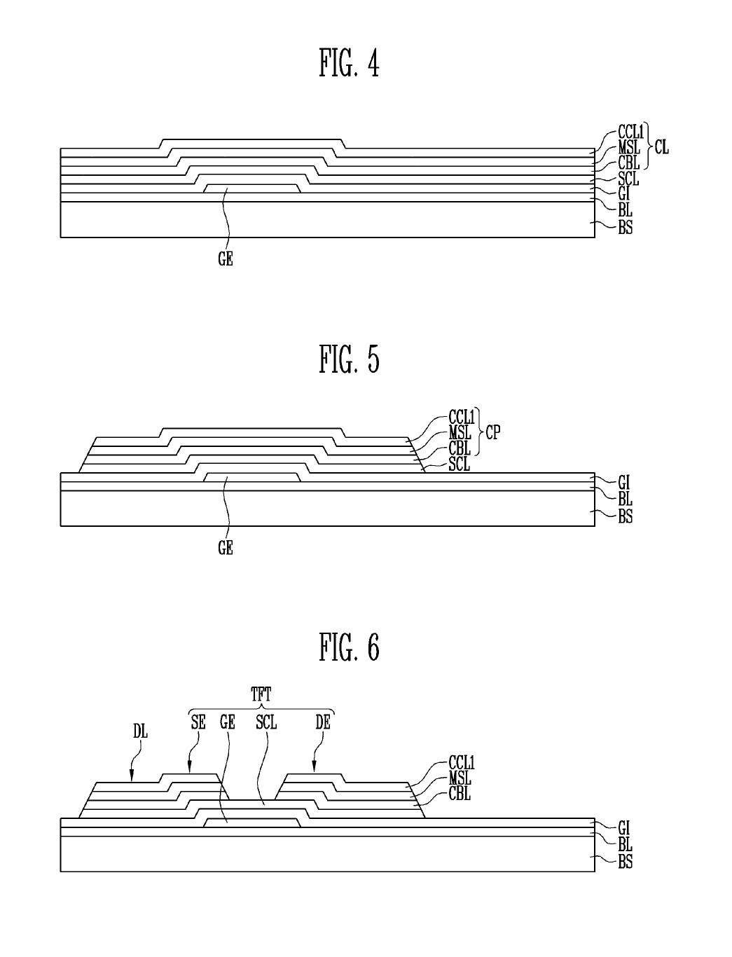

A method of fabricating the display device according to exemplary embodiments illustrated in FIGS. 1, 2, and 3 will be described below with reference to FIGS. 4, 5, 6, 7, 8, and 9. FIGS. 4, 5, 6, 7, 8, and 9 are respective cross-sectional views of a display device at various stages of manufacture, according to one or more exemplary embodiments.

Referring to FIG. 4, the insulating layer BL is formed on the base substrate BS. The base substrate BS includes a transparent insulating material to allow light to pass through. Further, the base substrate BS may be a rigid type substrate, and a flexible type substrate. The rigid type substrate includes at least one of a glass substrate, a quartz substrate, a glass ceramic substrate, and a crystalline glass substrate. The flexible type substrate includes a film substrate including at least one of a polymer organic material and a plastic substrate. The material included in the base substrate BS may have resistance (or heat resistance) to a high processing temperature involved during the fabricating process.

The insulating layer BL may include at least one of a silicon oxide layer and a silicon nitride layer. The insulating layer BL prevents or reduces impurities from being diffused to the thin film transistor TFT, and prevents or reduces moisture and oxygen from permeating. Further, the insulating layer BL may flatten a surface of the base substrate BS.

A gate line GL and a gate electrode GE are formed on the insulating layer BL. The gate electrode GE may be formed as a protruded part of the gate line GL. The gate electrode GE and the gate line GL may include at least one of aluminum AL, an aluminum alloy (Al-alloy), silver (Ag), tungsten (W), cooper (Cu), nickel (Ni), chrome (Cr), molybdenum (Mo), titanium (Ti), platinum (Pt), tantalum (Ta), neodymium (Nd), scandium (Sc), and an alloy thereof

A gate insulating layer GI is formed covering the gate electrode GE. The gate insulating layer GI may include at least one of a silicon oxide layer and a silicon nitride layer. For example, the gate insulating layer GI may have a structure in which the silicon oxide layer and the silicon nitride layer are stacked.

A semiconductor layer SCL is formed on the gate insulating layer GI. The semiconductor layer SCL may include an oxide semiconductor material. The oxide semiconductor material may include at least one of zinc (Zn), indium (In), gallium (Ga), and tin (Sn). For example, the semiconductor layer SCL may include an indium-gallium-zinc oxide (IGZO).

A conductive layer CL is formed on the semiconductor layer SCL. The conductive layer CL includes a barrier layer CBL disposed on the semiconductor layer SCL, a main wiring layer MSL disposed on the barrier layer CBL, and a capping layer CCL disposed on the main wiring layer MSL. A method of forming the conductive layer CL will be described in more detail below.

First, the barrier layer CBL is formed on the semiconductor layer SCL. The barrier layer CBL may be formed by depositing a transparent conductive oxide on the semiconductor layer SCL. The transparent conductive oxide may be at least one of an indium-zinc oxide (IZO), a gallium-zinc oxide (GZO), and an aluminum-zinc oxide (AZO). Here, a content of the zinc oxide (ZnO) in the transparent conductive oxide may be equal to or more than 70 wt % of the total weight.

The main wiring layer MSL is formed on the barrier layer CBL. The main wiring layer MSL may include a low resistance material, such as copper or a copper alloy.

A first capping layer CCL is formed on the main wiring layer MSL. The first capping layer CCL1 may include the same material as that of the barrier material CBL. That is, the first capping layer CCL may include at least one of an indium-zinc oxide (IZO), a gallium-zinc oxide (GZO), and an aluminum-zinc oxide (AZO). Here, a content of the zinc oxide (ZnO) in the transparent conductive oxide may be equal to or more than 70 wt % of the total weight. The zinc oxide (ZnO) is generally an amorphous material. Accordingly, the first capping layer CCL1 may prevent or block the copper material of the main wiring layer MSL from permeating into or being diffused into a grain boundary of the first capping layer CCL1. Particularly, the first capping layer CCL1 may prevent the generation of a copper oxide (CuO_{X}), which is generated by a direct contact of the inorganic passivation layer and the main wiring layer MSL when an inorganic passivation layer formed of silicon oxide (SiO_{X}) is deposited. The copper oxide (CuO_{X}) may cause lifting of the inorganic passivation layer, and corrosion of the main wiring layer MSL when a contact hole is formed.

Referring to FIG. 5, after the conductive layer CL is formed, a first etching process of etching the semiconductor layer SCL and the conductive layer CL together. The first etching process may be a wet etching process. A conductive pattern CP, which partially overlaps the gate electrode GE, may be formed by the first etching process. The conductive pattern CP may include the barrier layer CBL, the main wiring layer MSL, and the first capping layer CCL1.

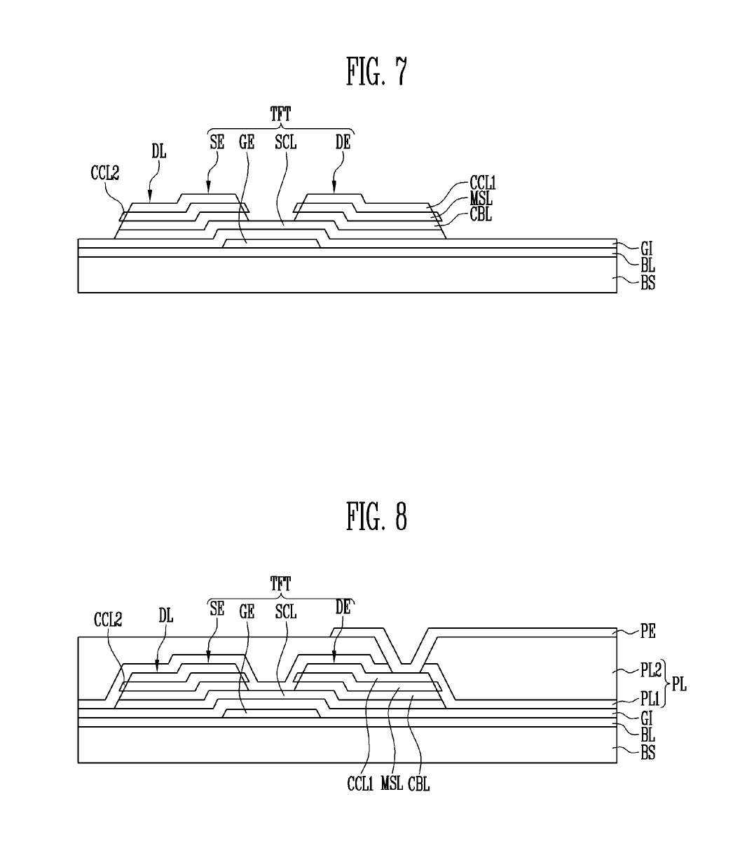

Referring to FIG. 6, after the first etching process, a second etching processing of partially etching the conductive patter CP is performed. The second etching process may be a wet etching process. In the second etching process, a portion of a region overlapping the gate electrode GE of the barrier layer CBL, the main wiring layer MSL, and the capping layer CCL may be removed. Accordingly, the semiconductor layer SCL overlapping the gate electrode GE may be exposed. The exposed region of the semiconductor layer SCL may be a channel region of the thin film transistor TFT.

Further, by the second etching process, a data line DL, a source electrode SE, and a drain electrode DE, including the barrier layer CBL, the main wiring layer MSL, and the first capping layer CCL1 may be formed. Accordingly, a thin film transistor TFT may be formed to include the gate electrode GE, the semiconductor layer SCL, the source electrode SE, and the drain electrode DE.

Referring to FIG. 7, after the second etching process, a second capping layer CCL2 for covering a lateral surface of the main wiring layer MSL exposed by the second etching process is formed. The second capping layer CCL2 may prevent or block copper included in the main wiring layer MSL from being diffused.

Further, the second capping layer CCL2 may include at least one of nickel-phosphorus, nickel-boron, gold-nickel, tin-lead, tin, and silver. For example, the second capping layer CCL2 may be nickel-phosphorus. Here, the second capping layer CCL2 may contain phosphorus of 8 wt % to 15 wt % of the total weight.

The second capping layer CCL2 may be formed by an n electroless plating method. For example, the second capping layer CCL2 may be an electroless nickel plated layer. Here, the electroless nickel plated layer may be formed on the lateral surface of the main wiring layer MSL by chemical reaction represented by Chemical Formulae 1 and 2 as provided below.

NiSO₄+2NaH₂PO₂+2HO→Ni+2NaH₂PO₃+H₂+H₂SO₄ [Chemical Formula 1]

NaH₂PO₂+H→H₂O+NaOH+P [Chemical Formula 2]

Here, the electroless plating method may form the second capping layer CCL2 by using hypophosphite as a reducing agent. The hypophosphite may be sodium hypophosphite.

In the electroless nickel plating using the hypophosphite as a reducing agent, the generated electroless nickel plated layer may generally be an amorphous layer of nickel (Ni) and phosphorous (P). Particularly, the electroless nickel plated layer which includes a content of phosphorus is 8 wt % to 15 wt % may be formed in a precise and flat layer when formed in a thickness 0.1 μm to 1.5 μm. When the content of phosphorus is equal to or greater than 8 wt %, the electroless nickel plated layer is deposited in an amorphous state, and therefore, generation of a pin hole in a grain boundary may be reduced or limited.

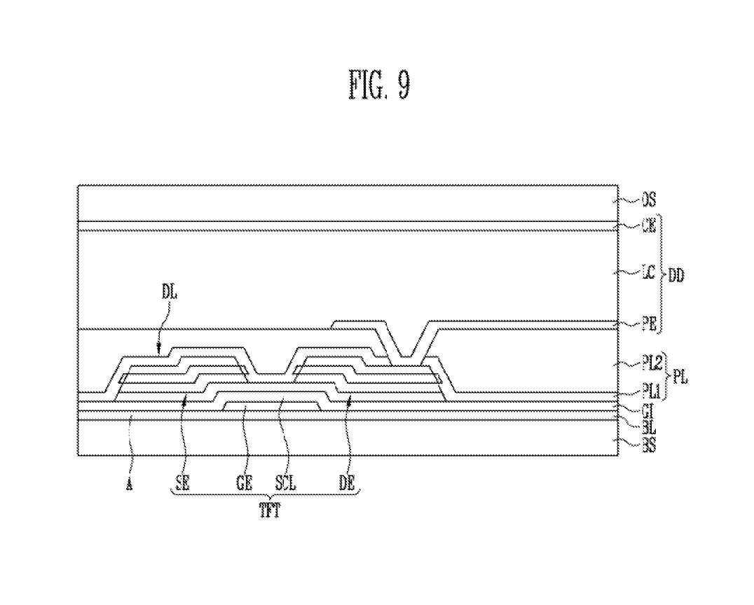

Referring to FIG. 8, after the second capping layer CCL2 is formed, a passivation layer PL is formed covering the thin film transistor TFT. The passivation layer PL may include an inorganic passivation layer PL1, and an organic passivation layer PL2 disposed on the inorganic passivation layer PL1.

Particularly, the inorganic passivation layer PL1 is formed covering the thin film transistor TFT. The inorganic passivation layer PL1 may include at least one of a silicon oxide layer and a silicon nitride layer. For example, the inorganic passivation layer PL1 may include the silicon oxide. Here, when the inorganic passivation layer PL1 is formed, the main wiring layer MSL is not exposed to the outside by the first capping layer CCL1 and the second capping layer CCL2, preventing or reducing oxidation of the main wiring layer MSL.

After the inorganic passivation layer PL1 is formed, the organic passivation layer PL2 is formed on the inorganic passivation layer PL1. The organic passivation layer PL2 may include at least one of acryl, polyimide (PI), polyamide (PA), and benzocycloubutene (BCB). That is, the organic passivation layer PL2 may be a flattening layer, which is transparent and flexible to smooth and flatten a curve of a lower structure.

After the passivation layer PL is formed, a contact hole CH, through which a part of the drain electrode DE is exposed, is formed by patterning the passivation layer PL. After the contact hole CH is formed, the first electrode PE connected to the drain electrode DE is formed by applying a transparent conductive material onto the passivation layer PL, and patterning the transparent conductive material. The first electrode PE may include a transparent conductive oxide, such as an Indium Tin Oxide (ITO) and/or an Indium Zinc Oxide (IZO).

Referring to FIG. 9, after the first electrode PE is formed, an optical layer LC including a plurality of liquid crystal molecules is disposed on the first electrode PE.

After the optical layer LC is disposed, an opposing substrate OS is disposed on the optical layer LC. The opposing substrate OS includes a second electrode CE on a surface facing the first electrode PE. The second electrode CE may include a transparent conductive oxide, similar to the first electrode PE.

The first electrode PE, the optical layer LC, and the second electrode CE, which are sequentially disposed on the passivation layer PL, configure a display device DD.

In the method of fabricating the thin film transistor substrate, the main wiring layer MSL is covered by the first capping layer CCL1 and the second capping layer CCL2, and then, the inorganic passivation layer PL1 including a silicon oxide is formed. Accordingly, the main wiring layer MSL is not in contact with the external environment, thereby preventing or reducing oxidation of the main wiring layer MSL. Accordingly, the method of fabricating the thin film transistor substrate may prevent or reduce deterioration of reliability of the thin film transistor from oxidation of the signal line.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A thin film transistor substrate, comprising:
a gate electrode disposed on a substrate;
a semiconductor layer partially overlapping the gate electrode, the semiconductor layer comprising an oxide semiconductor material;
a source electrode and a drain electrode disposed on the semiconductor layer, the source electrode and the drain electrode comprising a barrier layer, a main wiring layer disposed on the barrier layer, and a first capping layer disposed on the main wiring layer and being spaced apart from each other; and
second capping layers covering lateral surfaces of the main wiring layers of the source and drain electrodes.

2. The thin film transistor substrate of claim 1, wherein the second capping layers comprise at least one of nickel-phosphorus, nickel-boron, gold-nickel, tin-lead, tin, and silver.

3. The thin film transistor substrate of claim 2, wherein the second capping layers comprise nickel-phosphorus comprising 8 wt % to 15 wt % of phosphorus.

4. The thin film transistor substrate of claim 3, wherein thicknesses of the second capping layers are 0.1 μm to 1.5 μm.

5. The thin film transistor substrate of claim 4, wherein the barrier layers and the first capping layers comprise a transparent conductive oxide.

6. The thin film transistor substrate of claim 5, wherein the barrier layers and the first capping layers comprise at least one of an indium-zinc oxide (IZO), a gallium-zinc oxide (GZO), and an aluminum-zinc oxide (AZO).

7. The thin film transistor substrate of claim 6, wherein the transparent conductive oxide comprises at least 70 wt % of zinc oxide (ZnO).

8. The thin film transistor substrate of claim 1, wherein the oxide semiconductor material comprises at least one of zinc (Zn), indium (In), gallium (Ga), and tin (Sn).

9. A method of fabricating a thin film transistor substrate, the method comprising:
forming a gate electrode on a base substrate;
forming a semiconductor layer partially overlapping the gate electrode, the semiconductor layer comprising an oxide semiconductor material;
forming a conductive layer comprising a barrier layer, a main wiring layer, and a first capping layer sequentially disposed on the semiconductor layer;
patterning the conductive layer to form a conductive pattern that partially overlaps the gate electrode;
forming a thin film transistor, formation of thin film transistor comprising patterning the conductive pattern to remove a portion of the conductive pattern that partially overlaps the gate electrode; and
forming a second capping layer covering a lateral surface of the main wiring layer.

10. The method of claim 9, wherein the second capping layer comprises at least one of nickel-phosphorus, nickel-boron, gold-nickel, tin-lead, tin, and silver.

11. The method of claim 10, wherein the second capping layer comprises nickel-phosphorus comprising 8 wt % to 15 wt % of phosphorus.

12. The method of claim 11, wherein the second capping layer is at least formed via electroless nickel plating.

13. The method of claim 12, wherein the electroless nickel plating utilizes hypophosphite as a reducing agent.

14. The method of claim 13, wherein the hypophosphite is sodium hypophosphite.

15. The method of claim 9, wherein the barrier layer and the first capping layer comprise a transparent conductive oxide, the transparent conductive oxide comprising at least one of an indium-zinc oxide (IZO), a gallium-zinc oxide (GZO), and an aluminum-zinc oxide (AZO).

16. The method of claim 15, wherein the transparent conductive oxide comprises at least 70 wt % of zinc oxide (ZnO).

17. The method of claim 11, wherein thickness of the second capping layer is 0.1 μm to 1.5 μm.

18. The method of claim 9, wherein patterning the conductive layer comprises etching the conductive layer.

19. The method of claim 9, wherein patterning the conductive pattern comprises etching the conductive pattern.

20. The method of claim 9, wherein forming the second capping layer comprises forming second capping layers comprising the second capping layer, the second capping layers covering lateral surfaces of the main wiring layer comprising the lateral surface.
